(19) United States
(12) Patent Application Publication
(10) Pub. No.: US 2015/0162566 A1
(43) Pub. Date: Jun. 11, 2015

(54) ORGANIC ELECTROLUMINESCENT ELEMENT

(71) Applicant: Konica Minolta, Inc., Tokyo (JP)

(72) Inventor: Koutarou Kikuchi, Tokyo (JP)

(73) Assignee: Konica Minolta, Inc., Tokyo (JP)

(21) Appl. No.: 14/413,920

(22) PCT Filed: Jun. 26, 2013
(86) PCT No.: PCT/JP2013/067495

§ 371 Date: Jan. 9, 2015

(30) Foreign Application Priority Data
Jul. 27, 2012 (JP) 2012-166511

(51) Int. Cl. H01L 51/52

(52) U.S. Cl. CPC H01L 51/5262; H01L 51/5206; H01L 51/5221; H01L 51/5253

(57) ABSTRACT

An organic EL element is provided with: an organic electroluminescent element main body section (1), which is provided with electrodes consisting of an anode (12) and a cathode (14), and an organic compound layer (13), which is disposed between the anode (12) and the cathode (14), and which emits light when a voltage is applied to between the electrodes; and a glass cloth-containing light extracting member (2) that is provided on the outer side of the anode (12) and/or the cathode (14), which passes through light emitted from the organic compound layer (1).

### FIELD OF THE TECHNOLOGY

Present invention relates to an organic electroluminescent element applicable to for example a display, lighting equipment etc.

### BACKGROUND OF THE INVENTION

A lighting equipment which uses organic electroluminescent (EL) element (organic EL lighting equipment) is a self-luminous type equipment. Therefore, the organic EL lighting equipment is popularly researched and developed for the use in various types of displays, a backlight for liquid crystal display, a flat lighting equipment etc. Further, a display device, which uses the organic EL element (an organic EL display), has an advantageous display feature of better visibility and independency on viewing angle compared with a Braun tube display (Cathode Ray Tube; CRT) and liquid crystal display. Further, the organic EL has advantage that it is possible to reduce the weight and thin down a display, too.

Therein, the organic EL lighting equipment is uniformity flat light source, different from LED lighting equipment which uses a LED (Light Emitting Diode) of a point light source with high directivity. Therefore the organic EL lighting equipment has possibility of reducing thickness and weight, and has an advantage of fewer parts to be used for the equipment. Further, by using a flexible substrate, the organic EL lighting equipment might lead to realization of a lighting equipment with various shapes which has been difficult to achieve so far.

The organic EL lighting equipment comprises of plural members. Concretely, the organic EL lighting equipment is formed as an organic EL surface emitting device by installing an anode, an organic light emitting layer and a cathode etc. in this order on a surface of a transparent substrate. When voltage is applied to between the cathode and the anode, the organic light emission layer emits light. Then the light emitted by the organic light emission layer permeates through plural members of transparent substrates etc. and is emitted to the outside.

When the light emitted from the organic light emission layer is emitted to the outside, the emitted light could cause total reflection depending on the angle of incidence to the surface between the layers with different refractive indexes, then could permeate through insides of the display equipment. If this phenomenon is caused, the emitted light is not emitted to the outside. That is, the emitted light could be attenuated because of the total reflection etc. caused due to the difference in refractive indexes between layers, and could not be effectively emitted to the outsides of the equipment.

As a technique to enhance the out-coupling from the organic emission layer, the technique described in patent document 1 and 2 are known. A surface light emitting device described in patent document 1 has an optical sheet with light collection function. This optical sheet has light collecting function. This optical sheet consists of, for example, transparent substrate and optical layer, in which beads are dispersed in the binder. Further, an optical film described in the patent document 2 has a ruggedness structure portion. This ruggedness structure is formed on the film surface and units of ruggedness structure are repeated on the ruggedness surface at least in one direction.

### PRIOR ART DOCUMENT

### Patent Document

Patent document 1: JP 2003-100444 A

Patent document 2: JP2012-003074 A

### SUMMARY OF THE INVENTION

### Task to be Solved by the Invention

However, in the technology of the patent document 1 and 2, the weather resistance against the solar heat or sun light etc. is not considered. Therefore, if an organic EL element with improved light extraction efficiency is produced by using optical sheet and optical film disclosed by patent document 1 and 2, it is supposed that the weather resistance of the organic EL element is not enough. If such an organic EL element, which does not have enough weather resistance, is used, the organic EL element is deteriorated over years. Particularly, if these organic EL elements are used for light etc. installed outdoor, this deterioration progresses further.

The inventor have researched about the aging deterioration, and found out that the deterioration is caused by discoloration of the optical sheet or the optical film by heat or light. And the discoloration of the optical sheet or the optical film causes a decrease in luminance of the organic EL element. (That is, light extraction efficiency becomes lower.)

The invention of the present application was performed in view of the aforementioned problems. The task to be solved by the present invention is to provide both of good light extraction efficiency and good weather resistance at the same time

### Means to Solve the Task

The inventor has performed research to solve said task. As a result, the inventor has found that a out-coupling member, which includes glass cloth in the main body of the lighting organic EL element, solves the task and the invention was completed. That is, summary of the present invention is as follows.

1. An organic electroluminescent element comprising:

an organic electroluminescent element main body section having electrodes consisting of a cathode and an anode, and an organic compound layer disposed between said cathode and said anode, said organic compound layer emitting a light when a voltage is applied to between the electrodes, and

a light extracting member including a glass cloth provided outside at least one of said cathode and said anode, through either or both of which a light emitted from the said organic compound layer passes.

2. The organic electroluminescent element according to said 1, wherein said light extracting member is bonded to at least one of said cathode and said anode with an adhesive agent layer.

### Effect of the Invention

The present invention provides organic EL element, which has both of good light extraction efficiency and good weather resistance at the same time.

### BRIEF DESCRIPTION OF DRAWING

FIG. 1 is a cross-section of the embodiment of the present invention.

### EMBODIMENTS OF THE PRESENT INVENTION

The embodiments of the present invention (the present embodiments) are explained in the following part. But the present embodiments are not limited by following description, and are performed with any alteration in the range of the substantive part of the present invention.

[1. Structure of Organic EL Element]

An organic electroluminescent element of the present embodiment comprises an organic electroluminescent element main body section having electrodes consisting of a cathode and an anode, organic compound layer disposed between said cathode and said anode, said organic compound layer emitting a light when a voltage is applied to between the electrodes, and a light extracting member including a glass cloth provided outside at least one of cathode and anode, which transmits a light emitted from the organic compound layer.

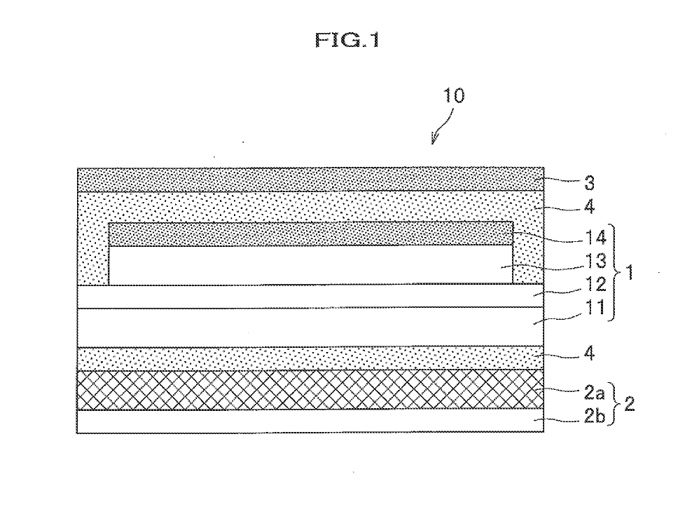

Accordingly the organic EL element of the present embodiment is explained referencing FIG. 1. Further, FIG. 1 is one example of the present embodiment. Any alteration can be performed in the range of the substantive part of the present invention.

The organic EL element 10 of the present embodiment is shown in the FIG. 1. an organic EL element main body section 1 and a sealing layer 3 are stacked on a glass cloth sheet 2 (a out-coupling member) in this order. The glass cloth sheet 2 and the organic EL element main body section 1 are bonded by an adhesion layer 4 (this layer is formed by coating adhesive agent). The organic EL element main body section 1 and the sealing layer 3 are bonded by the adhesion layer 4.

In the following part, at first, the glass cloth sheet 2 for the organic EL element 10 of the present embodiment is explained. Later, other parts except the glass cloth sheet 2 for the organic EL element 10 of the present embodiment are explained.

[1-1. Glass Cloth Sheet 2]

The glass cloth sheet 2 (a out-coupling member, hereinafter referred as to “sheet 2”) equipped with the organic EL element 10 is installed outside the transparent electrode (FIG. 1 shows an anode 12 of the organic EL element 10) which transmit the light emitted from an organic compound layer 13 explained later in detail. The Sheet 2 includes glass cloth. Shape of the out-coupling member is not limited to sheet, for example, it can be plate etc. The sheet 2 is normally formed by bonding a glass cloth substrate 2a and a light diffusion sheet 2b, wherein the light diffusion sheet 2b is formed on the surface of the glass cloth substrate 2a opposite to the surface on which the organic EL element main body section 1 is formed.

[Glass Cloth Substrate 2a]

The glass cloth substrate 2a is made of a glass cloth. The glass cloth is made of woven glass fiber. Concrete structure and species, additional agent etc. of such a glass cloth are not limited, and any kind of glass cloth can be used. Normally glass cloth is preferably colorless. Further, the glass cloth usable for the glass cloth substrate can be goods on the market or prepared by oneself. Glass cloth of one species can be used, or glass cloth of 2 or more species can be used in combination, too.

Further, as the glass cloth, grey goods of glass cloth, variously treated glass cloth and used glass cloth etc. can be used. However, the glass cloth is preferably glass cloth with treatment, more preferably, concretely, glass cloth with heat cleaning treatment or glass cloth with silane coupling treatment after heat cleaning treatment. Further detailed explanation will be made later.

A glass fiber used for glass cloth can be any glass fiber. Concrete examples of the glass fiber include E glass, D glass, T glass, C glass, ECR glass, A glass, L glass, S glass, YM31-A glass, and H glass etc. These glass fibers can be used alone or 2 or more species can be used in combination. Particularly E glass is preferable. These glass fibers can be produced in any production methods, or goods on the market can also be used.

Further, glass fiber can be both a long filament and a short filament. If the glass fiber is the long filament, for example, glass fibers paralleled and solidified as needed are usable. However, in this case, glass fibers are preferably spun. Spinning times are not limited, but, for example, 20 to 200 times per 100 cm would be appropriate for use. Both right twist (S twist) and left twist (Z twist) can be used. The types of spun fiber include single-twist yarn, plied yarn, plied yarn of different nature of stand, hard-twist yarn, corkscrew yarn, and piece twisted yarn.

If glass fiber is short filament, for example, spun yarn can be used. Spun yarn is produced from glass fibers which were spun and connected. Twist level of short filament is similar to long filament.

Further, a count of glass fiber is not limited, but it should be normally 1 tex or more, preferably 5 tex or more and normally less than 1000 tex, preferably 850 tex, more preferably 200 tex or less, particularly preferably 150 tex or less.

When glass cloth is made of glass fibers, any weave methods of glass cloth can be used. The types of weave method include a plain weave, twill weave, leno weave, stain weave, three-axial weave, and horizontal strips weave etc. Weave methods can use, for example, jet weave machine (for example, air jet weave machine, water jet weave machine), Sulzer weave machine, Rapier weave machine etc. These weave machines can be used in combination as appropriate.

Density of the glass fiber in the formed glass cloth is not limited especially. However, when warp yarn or weft yarn are used, it is preferable that 10 or more yarns should be woven into a 25 mm square glass cloth, more preferably 40 or more yarns, and preferably 80 or more yarns, more preferably 60 or more yarns. If the density of glass fibers is in those ranges, space between glass fibers can be smaller and ultimate tensile strength becomes strong enough. Further, flexibility and softness of the glass cloths become good enough, and handling property is improved.

[Light Diffusion Sheet 21)]

The light diffusion sheet 2b which consist of sheet 2, is formed on the surfaces of the glass cloth 2a. The light diffusion sheet 2b can be formed on only one side of the glass cloth 2a or can be formed on both sides of the glass cloth substrate 2a. Further, the light diffusion sheet 2b can be omitted. Further, the glass cloth can be impregnated with a material which composes the light diffusion sheet, and the glass cloth substrate 2a and the light diffusion sheet 2b can be integrally molded.

The type of the light diffusion sheet 2b is not particularly limited, but, for example, inorganic material (silica etc.), polyvinyl chloride resin, vinyl ester resin, acryl resin etc. can be used. Further, in addition to those material, for example, saccharides (monosaccharide, oligosaccharide, polysaccharide etc.) can be included. Especially if monosaccharide is included, the monosaccharide itself can be included from the beginning, or monosaccharide, which is generated from oligosaccharide or polysaccharide and polysaccharide breakdown enzyme, can be included. Saccharides include cyclodextrin, chitosan, and pullulan etc. Each of these can be used alone or 2 or more of these saccharides can be used in combination at any ratio. As polysaccharide breakdown enzyme, for example, enzyme, which breaks down polysaccharide to monosaccharide (for example, chitosanase, pullulanase, amylase etc.), transglycosylation enzyme (for example, cyclodextrin glucosyl transferase etc) can be used.

[Property of Sheet 2]

The property of the sheet 2 is not limited. However, haze value of sheet 2 is preferably more than 90%, more preferably more than 93%, further preferably more than 95%, especially preferably more than 97%. If haze value is in those ranges, better light extraction efficiency can be achieved.

Haze value can be calculated by using the following equation (1).

Haze value (%)={diffuse transmittance (%)/total light transmittance (%)}×100 (1)

Further, haze value can be measured by the method described in JIS-K-7136 “how to measure the haze value of plastic transparent material” or described in ISO14782 “Plastics-Determination of haze for transparent materials”

Further, total light transmittance of the sheet 2 (total light transmittance) is preferably more than 40%, more preferably 41% or more, especially preferably 44% or more. If total light transmittance is in those ranges, better light extraction efficiency can be achieved. The total light transmittance can be measured by the method described in JIS-K-7361-1 “how to measure the total light transmittance of plastic transparent material” or in ISO13468-1 “Plastics-Determination of the total luminous transmittance of transparent materials”.

Thickness of the sheet 2 can be, for example, 0.1 mm or more and 0.5 mm or less. If the thickness of the sheet 2 is in this range, the organic EL element, which has better weather resistance, flexibility and light extraction efficiency, can be produced.

Further, the weight of the sheet 2 can be, for example, 100 g to 500 g in 1 m². If the weight of the sheet 2 is in this range, the organic EL element, which has better weather resistance, flexibility and light extraction efficiency, can be produced.

[1-2. Other Components]

As described above, the organic EL element 10 of the present embodiment has sheet 2 including glass cloth. Further, other than the sheet 2, the organic EL element 10 of the present embodiment has the organic EL element main body section 1 shown in FIG. 1, including sealing layer 3 and adhesion layer 4. However, the sealing layer 3 and adhesion layer 4 can be suitably omitted.

Further, in the organic EL element 10 shown in FIG. 1, emitted light is extracted from the anode 12. However, extraction direction is not limited to this. The emitted light can be extracted from the cathode 14 or from both the anode 12 and cathode 14. Further, depending on the direction of extracting emitted light, for example, said sheet 2 can be formed on the light extraction surface of the cathode 14. That is, if the light is extracted from the cathode 14, the sheet 2 can be installed outside the cathode 14. Further, if light is extracted from both the anode 12 and cathode 14, the sheet 2 can be installed on both the outside the anode 12 and the outside the cathode 14.

[Organic EL Element Main Body Section 1]

The organic EL element main body section consists of the anode 12, the cathode 14 and an organic compound layer 13 installed between the anode 12 and the cathode 14, the organic compound layer 13 emitting light when voltage is applied between the electrodes (anode 12 and cathode 14). The extracted light from the organic EL element 10 is normally the light emitted from the organic EL element main body section 1.

In addition to a light emission layer which directly emits light, the organic EL element main body section 1 normally has, various organic layers, for example, carrier (hole and electron) injection layer, carrier blocking layer and carrier transport layer etc. Further, the organic EL element main body section 1 is normally composed of an element substrate, electrodes, and a light emission layer in addition to said various organic layers which are stacked up. Concretely, as FIG. 1 shows, the element substrate 11, the anode 12, the organic compound layer 13 (light emission layer etc.) and the cathode 14 are stacked up to form the organic EL element main body section 1.

Further, in the organic EL element main body section 1, preferable layers of the organic compound layer 13 are as follows. Therein the following (1)˜(6) are stacked up sequentially. Normally, the layer listed in (1) is stacked on the anode, and other layers are stacked up sequentially toward the cathode.
(1) Light emission layer/electron transfer layer
(2) Hole transfer layer/light emission layer/electron transfer layer
(3) Hole transfer layer/light emission layer/hole blocking layer/electron transfer layer
(4) Hole transfer layer/light emission layer/hole blocking layer/electron transfer layer/electron injection layer (cathode buffer layer)
(5) Hole injection layer (anode buffer layer)/hole transfer layer/light emission layer/hole blocking layer/electron transfer layer/electron injection layer
(6) Hole injection layer/hole transfer layer/light emission layer/electron transfer layer/electron injection layer

Following is explanation of the parts, which compose the organic EL element main body section 1. However, composition of the organic EL element main body section 1 is not limited to the following description.

(Element Substrate 11)

The element substrate 11 (substrate, base plate, board, supporting body etc.) can be made of a transparent material such as glass or plastics. Further, the element substrate 11 is preferably made of flexible material such as thin film glass or transparent resin film etc. Further, the element substrate 11 is preferably made of transparent resin material. Therefore, the element substrate 11 is preferably made of transparent resin film.

Transparent resin films include polyester such as polyethylene terephthalate (PET), and polyethylene naphthalate (PEN) etc., polyethylene, polypropylene, cellulose ester group or its derivatives of Cellophane (registered trademark), cellulose diacetate, cellulose triacetate, cellulose acetate butyrate, cellulose acetate propionate (CAP), cellulose acetate phthalate (TAC), and cellulose nitrate etc., polyvinylidene chloride, polyvinylalcohol, polyethylene vinyl alcohol, syndiotactic polystyrene, polycarbonate, norbornene resin, polymethylpentene, polyether ketone, polyimide, polyether sulfone (PES), polyphenylene sulfide, polysulfone group, polyether imide, polyether ketone imide, polyamide, fluoro resin, Nylon (registered trademark), polymethylmethacrylate, acryl, polyarylate, Arton (registered trademark, made by JSR Co.) and Apel (registered trademark, made by Mitsui Chemicals Inc.) of cycloolefin. These can be used alone or 2 or more can be combined at any rate.

Further, if the transparent resin film is used as the element substrate 11, a gas barrier layer described later is preferably formed on the transparent resin film.

(Gas Barrier Layer)

One layer or 2 or more layers of the gas barrier are preferably formed between the element substrate 11 and the organic compound 12 for the purpose of excluding moisture. FIG. 1 does not show any gas barriers.

Gas barrier layers include, for example, inorganic film, organic film and hybrid film using said both of the films. The water vapor permeability of the gas barrier layer is preferably 0.01 g/(m²·day·1013 hPa) or less. High barrier film with 10⁻³ ml/(m²·day) or less of oxygen permeability and 10⁻⁵ g/(m²·day) or less of water vapor permeability is more preferable.

A material used for a gas barrier layer is not particularly limited, but preferably materials which suppress ingress of water and oxygen that deteriorate the element. For example, metal oxide of silicon oxide, silicon dioxide etc., and metal nitride of silicon nitride etc. can be used. Further, a material having a laminated structure consisting of inorganic layer and organic layer is preferable to strengthen the gas barrier layer. Sequence of the inorganic layer and the organic layer is not limited, but they are preferably alternately laminated for several times.

Producing method of the gas barrier is not limited. For example, vacuum deposition method, spattering technique, reactive spattering technique, molecular beam epitaxy, cluster ion beam method, ion plating method, plasma polymerization, plasma polymerization under normal pressure, plasma CVD (Chemical Vapor Deposition), laser CVD, heat CVD, and coating method etc. can be used.

(Anode 12)

The anode 12 is an electrode film which supplies (injects) holes to the organic compound 1 (concretely light emission layer). The type and property of the anode 12 is not particularly limited, and can be chosen as appropriate. For example, anode 12 can be made of a material having a great work function (4 eV or more), such as, metal, alloy, electro conductive compound and the mixture of these electrode material. On another occasion, anode 12 can be made of light transmissive materials (transparent electrode) such as indium tin oxide, indium zinc oxide or the like.

A refractive index of the anode 12 is not limited, but preferably 1.5 or more, more preferably 1.55 or more. Further, it is preferably 2 or less, more preferably 1.85 or less. A sheet resistance (surface resistance) of the anode 12 is also not limited, but preferably less than several hundred Ω/sq. Further a film thickness of the anode 12 is not limited. The thickness varies depending on the material used, but it is normally 10 nm or more. Also, it is normally 1000 nm or less, preferably 200 nm or less.

(Organic Compound Layer 13)

The organic compound layer 13 has normally, in addition to a light emission layer, various organic layers such as a carrier (hole and electron) injection layer, a carrier blocking layer and a carrier transfer layer etc. In following part, structure of each organic layer will be explained, but these organic layers are not shown in FIG. 1. Besides, since known materials can be used, explanation for concrete materials etc. of various organic layers is omitted.

Light Emission Layer

The light emission layer is the layer which emits light when holes which are injected directly from anode 12 or through a hole transfer layer, and electrons which are injected directly from cathode 14 or through electron transfer layer, recombine. A part that emits light can be the inside of the light emission layer or on the surface between the light emission layer and the adjacent layer.

The light emission layer preferably consists of an organic light emission material which includes host compound (host material) and light emission compound (light emission dopant compound). Such a structure of the light emission layer shows any color of emission if light wave length of the light emission material and species of included light emission material are controlled suitably. Further, by forming light emission layer in such a way, the light emission compound in the light emission layer can emits light.

A thickness of the light emission layers is, for example, suitably designed depending on the desired light emission property. For example, the total thickness of the film is preferably 1 nm to 200 nm, in consideration of homogeneity of the light emission layer, preventing from applying unnecessarily high voltage during light emission, and improving stability of light emission against driving current. The total thickness of the light emission layer is particularly preferably 30 nm or less in consideration of a low driving voltage.

A host compound included in the light emission layer is preferably the compound, which phosphorescence quantum yield of phosphorescence at room temperature (25° C.) is preferably 0.1 or less, more preferably 0.01 or less. Also, the ratio of the volume of the host compound in the light emission layer to that of the total various compounds in the light emission layer is preferably 50% or more.

As the light emission compounds in the light emission layer, for example, phosphorescence compound (phosphorescent compound, phosphorescence emission compound), fluorescence emission compound and the like can be used. Further, one light emission layer can include one kind of the light emission compound or plural kinds of different light emission compounds whose maximum emission wave lengths are different from one another. If the plural kinds of light emission compounds are used, lights of different wave length are mixed and emitted. Thereby lights of any colors can be obtained and emitted. Concretely, for example, if blue light emission compound, green light emission compound and red light emission compound (3 kinds of the light emission compound) are included in the light emission layer, white light can be obtained.

Injection Layer (Hole Injection Layer, Electron Injection Layer)

An injection layer is the layer for lowering driving voltage and improving brightness of the light emission. The injection layer is normally installed between an electrode and a light emission layer. There are generally two types of injection layers. That is, one is a hole injection layer, where holes (carrier) are injected, and the other is an electron injection layer, where electrons (carrier) are injected. The hole injection layer (cathode buffer layer) is installed between the anode 12 and the light emission layer or the hole transfer layer. On the other hand, electron injection layer (cathode buffer layer) is installed between the cathode 14 and the light emission layer or the electron transfer layer.

Blocking Layer (Hole Blocking Layer, Electron Blocking Layer)

A blocking layer is a layer to block the carrier (hole, electron) transfer. There are generally two types of blocking layers. That is, one is a hole blocking layer, which blocks hole (carrier) transfer, and the other is an electron blocking layer, which blocks electron (carrier) transfer.

The hole blocking layer is, in broad sense, the layer having the function (electron transfer function) of electron transfer layer (described later). The hole blocking layer consists of a material which has electron transfer function and whose hole transfer function is low. If this hole blocking layer is installed, the injection balance between hole and electron is improved in the light emission layer. Further, in this way, the provability of recombination of electron and hole can be improved.

Besides, if necessary, the composition of the electron transfer layer, described later, can be applied to the hole blocking layer. Further, the hole blocking layer should be installed adjacent to the light emission layer, if the hole blocking layer is installed.

On the other hand, the electron blocking layer, in broad sense, has the functions (hole transfer function) as the hole transfer layer (described later). The electron blocking layer consists of a material, which has hole transfer function and whose electron transfer function is low. If these electron blocking layers are installed, the injection balance between hole and electron is improved in the light emission layer. Further, in this way, the probability of recombination of electron and hole can be improved. Besides, if necessary, the structure of hole transfer layer, described later, can be applied to the electron blocking layer.

Thickness of the blocking layer is not particularly limited, but preferably more than 3 nm, more preferably 5 nm or more. Also, it is preferably 100 nm or less, more preferably 30 am or less.

Transfer Layer (Hole Transfer Layer, Electron Transfer Layer)

The transfer layer is the layer to transfer carrier (hole and electron). There are generally two types of transfer layers. One is a hole transfer layer, which transfers hole (carrier), and the other is an electron transfer layer, which transfers electron (carrier).

The hole transfer layer receives holes from the anode 12 and transfer (inject) the holes into the light emission layer. The hole transfer layer is installed between the anode 12 or the hole injection layer and the light emission layer. On the other hand, the hole transfer layer functions as an obstacle to block electrons flow from cathode 14. Therefore, the term hole transfer layer, in broad sense, includes the hole injection layer and/or the electron blocking layer. Besides, the hole transfer layer can be installed as a single layer or as plural layers.

The electron transfer layer receives electrons from the cathode 14 and transfer (inject) the electron into the light emission layer. The electron transfer layer is installed between the cathode 14 or the electron injection layer and the light emission layer. Also, the electron transfer layer functions as an obstacle to block holes flow from anode 12. Therefore, the term electron transfer layer, in broad sense, includes the electron injection layer and/or the hole blocking layer. Besides, the electron transfer layer can be installed as a single layer or as plural layers.

An electron transfer compound (this may also be used as holes blocking compound), which is used for the electron transfer layer (If the electron transfer layer is a single layer, that electron transfer layer refers to the single layer. If the electron transfer layer is plural, the electron transfer layer refers to the layer nearest to the light emission layer.) is not particularly limited. A material having a function to transfer (transport) the electron injected from the cathode 14 to the light emission layer is normally usable as an electronic material used for the electron transfer layer.

(Cathode 14)

The cathode 14 is an electrode film to supply (inject) electron to the light emission layer. Material constituting the cathode 14 is not particularly limited, but normally electrode material with small work function (4 eV or less), for example, metal (electron injective metal), alloy, electro-conductive compound or mixture of them.

When light is extracted from the cathode 14 side in the organic EL element 10, cathode 14 can consist of an electrode material having light permeability in the same way as the anode 12. In this case, for example, metal film consisting of an anode-forming electrode material whose thickness is, for example, 1 nm to 20 nm, thereafter, a film consisting of cathode-forming conductive transparent materials is formed on the metal film, thereby, a transparent or semitransparent cathode 14 can be formed.

(Sealing Layer 3)

The sealing layer 3 protects the organic EL element main body section 1 and the like from the external air. A structure of the sealing layer 3 is not limited, but when the sealing layer 3 is flexible material, the sealing layer 3 is preferably a laminated layer composed of a resin layer and a gas barrier layer.

When the sealing layer 3 is flexible material, the thickness of the sealing layer 3 is not limited, but preferably 10 μm to 300 μm in consideration of handling in the production, tensile strength, the gas barrier layer's stress-resistant cracking strength and the like. In addition, the thickness of the sealing layer 3 can be measured by a micrometer. The thickness is a mean value of values measured at 10 points in the vertical direction (direction vertical to FIG. 1 sheet) and values measured at 10 points in the horizontal direction (direction horizontal to FIG. 1 sheet) of the sealing layer 3.

The flexible material for the sealing layer 3 is not limited. For example, thermoplastic film materials used as various wrapping film such as ethylene tetrafluoro ethylene copolymer (ETFE), high density polyethylene (HDPE), orientated polypropylene (OPP), polystyrene (PS), polymethyl methacrylate (PMMA), orientated nylon (ONy), polyethylene terephthalate (PET), polyethylene naphthalate (PEN), polycarbonate (PC), polyimide, and polyether styrene (PES) can be used. These resins can be used alone or 2 or more can be combined at any rate.

Further, laminated films consisting of different types of films by means of coextrusion or laminated films consisting of films with different lamination direction can also be used as thermoplastic resin films. Further, to achieve desired property, various combination can be used regarding the density and molecular distribution of films.

The gas barrier layer is not particularly limited. For example, inorganic deposited film and metal leaf can be used. Inorganic deposition films are cited in the following references: “Handbook of thin film”, p. 879 901 (Japan Society for the Promotion of Science), “Handbook of vacuum technology”, p. 502 509, p. 612, p. 810 (Nikkan Kogyo Shinbun Co.), “Handbook of vacuum, enlarged and revised edition”, p. 132 134 (ULVAC, Japan Vacuum Technology Co.).

Concretely, inorganic deposition films include metals like In, Sn, Pb, Au, Cu, Ag, Al Ti, Ni and MgO, SiO, SiO₂, Al₂O₃, GeO, NiO, CaO, BaO, Fe₂O₃, Y₂O₃, TiO₂, Cr₂O₃, SixOy (x=1, y=1.5˜2.0), Ta₂O₃, ZrN, SiC, TiC, PSG, SI₃N₄, SiN, single crystal Si, amorphous Si, and W. Besides, concretely, metal leafs include metal materials like Al, Cu, Ni etc. and alloy materials like stainless, aluminum alloy etc. Each can be used alone, or two or more of them can be combined at any rate. Especially, as a metal leaf, aluminum is preferable in consideration of processability and cost.

The film thickness of the gas barrier layer is not particularly limited. But, when the gas barrier layer is formed with an inorganic deposition, the film thickness is generally 5 nm or more, preferably 10 nm or more. Also, it is generally 1000 nm or less, preferably 300 nm or less. Further, when the gas barrier layer consists of, for example, metal leaf, the film thickness is generally 1 μm or more, preferably 10 μm, more preferably 20 μm. Also, it is generally 2 mm or less, preferably 100 μm, more preferably 50 μm in consideration of handling in the production and thinning panel.

Also, a water vapor permeability of the gas barrier layer is preferably 0.01 g/(m² day) or less in consideration of crystallization of organic compound layer 1, occurrence of dark spot because of exfoliation of cathode 14 and lifetime improvement of the organic EL element 10. Further, the water vapor permeability can be measured by mainly MOCON method based on JIS K7129B method (1992).

The oxygen permeability of the gas barrier layer is preferably 0.01 ml/(m² day 1013hPa) or less in consideration of crystallization of organic compound layer 1, the occurrence of dark spot because of exfoliation of cathode 14 and lifetime improvement of the organic EL element 10. Further, the oxygen permeability can be measured by mainly MOCON method based on JIS K7126B method (1987)

In addition, the gas barrier layer can have a protection layer. Further, a resin layer laminated on the gas barrier layer can be a single resin layer, or a layer of the laminated plural resin layers. In addition, the gas barrier layer can be a single layer or laminated plural gas barrier layers.

(Adhesion Layer 4)

The adhesion layer 4 is the layer which bonds the organic EL element main body section 1, sheet 2 and the sealing layer 3. That is, the sheet 2 (out-coupling member) is bonded to the anode 12 with the adhesion layer 4. However, when the sheet 2 is installed outside the cathode 14, the sheet 2 (out-coupling member) is bonded to cathode 14 with the adhesion layer 4. The adhesion layer 4 is formed generally by coating and solidifying adhesion agent.

Such an adhesion agent is not limited, but for example, photo curing type liquid adhesion agent, heat curing type liquid adhesion agent and like can be used. Specifically, adhesion agent such as photo curing type and heat curing type sealing agent with reactive vinyl group of acrylic acid group oligomer and methacrylic acid group oligomer, humidity curing type adhesion agent like 2-cyanoacrylic ester etc., heat and chemical curing type (two liquid mixture) adhesion agent like epoxy group etc., and UV curing type epoxy resin adhesion agent of cation curing type can be used.

An adhesion agent preferably includes filler. The amount of filler is not limited, but preferably 5 volume % to 70 volume % to the total adhesion volume in consideration of adhesive strength. In addition, a size of the filler is not limited, but preferably 1 μm to 100 μm in consideration of adhesion strength and thickness of adhesion after laminating and pressing.

Examples of added filler include metal oxides like soda glass, non alkali glass or silica, titan dioxide, antimony oxide, titania, alumina, zirconia, and tungsten oxide.

As described above, for example, the adhesion layer 4 is formed by coating and curing said adhesion agent. However when a liquid adhesion agent is used as adhesion agent, process is preferably done under reduced pressure of 1×10⁻² Pa to 10 Pa in consideration of stability of the bonding, preventing air bubbles from entering into a bonding part and maintaining the flatness of the flexible member.

[2. Producing Method of Organic EL Element]

Next the producing method of the organic EL element of the present embodiment is explained. The method explained as follows is one of the possible producing methods of the organic EL element of the present embodiment. The producing methods of the organic EL element of the present embodiment are not limited to the following explanation.

The organic EL element of the present embodiment can be formed by laminating adhesion agent, an organic compound layer 1, adhesion agent, and a sealing agent layer 3 on the seat 2 including glass cloth and then by curing the adhesion agent. Explanation on a concrete process is omitted since any process can be applicable. It should be noted that the organic EL element of the present embodiment includes glass cloth. This glass cloth is preferably given a predetermined treatment.

For the glass cloth, mainly heat cleaning treatment, silane coupling treatment, impregnation treatment and drying treatment are preferably performed. That is, at first, glass cloth is heat-cleaned (heat cleaning treatment). Then the heat-cleaned glass cloth is preferably treated with silane coupling agent (silane coupling agent treatment). Further, the glass cloth treated with silane coupling agent is impregnated in the binder solution (impregnation treatment). Thereafter the glass cloth is preferably dried (drying treatment). The glass cloth, which is treated with these treatments, is preferably included in the organic EL element of the present embodiment. These treatments are explained as follows.

(Heat Cleaning Treatment)

In the present treatment, glass cloth is heat-cleaned. Concretely, glass cloth is heated. By this treatment, binder agent of grey goods of glass cloth can be excluded. A condition of heat cleaning treatment is not limited, but for example, heat cleaning can be performed with use of a heating furnace of 300° C. to 400° C. Further, treating time is not limited, but generally 24 hours or more, preferably 48 hours or more. Also, it is generally 120 hours or less, preferably 96 hours or less.

(Silane Coupling Agent Treatment)

In the Present Treatment, the Glass Cloth, which was Heat-Cleaned, is Treated with Silane coupling agent. By this treatment, the surface of glass cloth is modified and the adhesion strength between the glass cloth and the adhesion layer 4 can be improved. The condition of the silane coupling treatment is not limited, but generally the solution, in which silane coupling agent is solved, (silane coupling agent solution) is used for glass cloth treatment. By this process, silane coupling agent is stuck to or fixed to the surface of the glass cloth.

A solvent, which solves the silane coupling agent, is not limited, but, for example, water, lower alcohol like methyl alcohol, ethyl alcohol, propyl alcohol, isopropyl alcohol, butyl alcohol, isobutyl alcohol, and ether like isopropyl ether, tetrahydrofuran, dioxane can be used. Each can be used alone or two or more can be combined at any rate.

A concentration of the silane coupling is not particularly limited, but generally 0.01 mass % or more, preferably 0.1 mass % or more. Also, it is generally 20 mass % or less, preferably 5 mass % or less. By impregnating the glass cloth in the silane coupling agent solution, the silane coupling agent treatment can be performed. Further, after the glass cloth is impregnated in the silane coupling agent solution, the glass cloth is preferably dried before the impregnation treatment described later.

(Impregnation Treatment)

In the present treatment, the glass cloth, which was treated with the silane coupling agent, is impregnated in the binder solution including binder. Thereby glass cloth is integrated with binder. In the impregnation treatment, usable binder is not limited, but for example, inorganic resin like vinyl acetate group resin, vinyl chloride group resin, acryl group resin, vinyl ester group resin, and colloidal silica can be used. Each can be used alone or two or more can be combined at any rate.

Among these binder, inorganic resin, especially colloidal silica, is preferable. When the colloidal silica is used as binder, the preferable binder solution includes water and a saccharide treated by enzyme as well as colloidal silica. Such a saccharide is, for example, the same saccharides explained above in [1. Structure of organic EL element]

(Drying Treatment)

In the present treatment, the glass cloth impregnated in the binder solution is dried. The upper limit of the drying is not limited. For example drying treatment can be performed at 25° C. for 24 hours. Thereafter glass cloth produced in this way is appropriate for the organic EL element of the present embodiment.

### EXAMPLES

The organic EL element of the present embodiment is explained more concretely with the following examples.

Production of the Organic EL Panel A˜F

### Example 1

At first, an element substrate with a gas barrier layer was produced by using a CVD apparatus, which forms a film by plasma CVD method. The gas barrier layer on the surface of the element substrate includes a silicon nitride film.

As an element substrate, a 188 μm thick PET film (polyethylene terephthalate film “Lumiler” made by Toray Advanced Film Co., Ltd.) was used. The element substrate was placed on a specific place in the vacuum chamber and the vacuum chamber was closed up.

Then air in the vacuum chamber was evacuated until the pressure reached 0.01 Pa. Then, as reaction gas, silane gas, ammonia gas and nitrogen gas were introduced into the vacuum chamber. The flow rate of silane gas was 50 mL/min, flow rate of ammonia gas was 100 mL/min and flow rate of nitrogen gas was 150 mL/min in the condition of 1013 hPa and 25° C. Evacuation was controlled so that the pressure in the vacuum chamber should be 100 Pa.

Then high frequency AC power of 750 W was supplied to an electrode, and a 100 nm thick gas barrier film (silane nitride film) was formed on the surface of the element substrate. By this way, the element substrate, which had a gas barrier property was produced. The oxygen permeability and water vapor permeability of the element substrate was 0.01 ml/(m²·day) or less and 0.01 g/(m²·day) or less respectively.

On the obtained element substrate, ITO (Indium Thin Oxide) as a 110 nm thick anode was formed by a spatter apparatus. Then patterning of ITO was performed by photolithography method, then organic compound layer and a cathode were formed on it by vacuum deposition method, and the organic EL element main body section was produced. The organic EL element main body section obtained in this way had 4 divisions of light emission pattern: 20 mm×16.5 mm×4 picture elements (total size of the 4 divisions was 41×34 mm.).

Next, a light extraction sheet was produced as follows.

A binder solution was obtained by mixing colloidal silica, cyclodextrin, chitosan, pullulan and enzyme (cyclodextrin glucosyl transferase, chitosanase, pullulanase and amylase) into the water, so that the solid content concentration should be 30 weight part, viscosity at 25° C. should be 250 mPa·s, pH at 25° C. should be 11 and specific gravity should be 1.3 at 25° C. Then a glass cloth (H201 made by Unitika glass fiber Co.) was impregnated into the binder solution, then a impregnated glass cloth was dried in the drying condition at 120° C. for two minutes, and a light extraction sheet A was produced.

A heat curing type adhesion agent Structbond E-413 (made by Mitsui Chemicals Co.) was coated on the surface of the light extraction sheet A. An organic EL element main body section was placed on the coated surface of the light extraction sheet A so that the element substrate of prepared organic EL element main body section should touch the light extraction sheet A. Thereafter, under the reduced-pressure environment of 1×10⁻² Pa, both of them was crimped with a vacuum laminator under the pressure of 0.1 MPa at 100° C. for 60 minutes. Thereafter as curing process, they were heated at 100° C. for 30 minutes.

Next, a barrier film (sealing material), which had a 30 μm thick gas barrier film (gas barrier layer) composed of an aluminium foil laminated on a 50 μm thick polyethylene terephthalate film, was produced. Then the heat curing type adhesion agent Structbond E-413 (made by Mitsui Chemicals Co.) was coated on the cathode of said organic EL element main body section, then the sealing material was placed on it. In this process, the cathode and the aluminum foil of the sealing material were installed on each surface of the heat curing type adhesion agent. Thereafter, the organic EL element main body section and the sealing material were fixed adhesively, in the same way as the fixation of the light extraction sheet A to the organic EL element main body section. In this way, the light extraction sheet A, the organic EL element main body section and the sealing material were adhesively fixed through the adhesion layer, and an organic EL panel A was produced.

### Example 2

The organic EL panel B was produced in the same way as example 1 except for the fact that the light extraction sheet B, which was produced in the following method, was used instead of the light extraction sheet A.

The light extraction sheet B was produced in the following way.

To vinyl chloride resin (Kanebirack made by Kaneka Co.), whose main contents were copolymer of vinyl chloride and vinyl acetate, 100 part by weight, dibutyl phthalate 15 part by weight as plasticizer was added, and methyl ethyl ketone 75 part by weight was added, then a solution was diluted. Heat-cleaned glass cloth (H201 made by Unichika glass fiber Co.) was impregnated into the solution. Then methyl ethyl ketone was evaporated by drying at 120° C. In this way the glass cloth impregnated with resin composition was obtained.

On both sides of the glass cloth, 80 μm thick transparent soft vinyl chloride sheets (Altoron GX446V6 made by Mitsubishi Chemicals MKV Co.) were laminated, and the surfaces of the sheets was heated and pressured by heat-press at 110° C. to produce the light extraction sheet B.

### Example 3

The organic EL panel C was produced in the same way as example 1 except for the fact that the light extraction sheet C, which was produced in the following method, was used instead of the light extraction sheet A.

The light extraction sheet C was produced in the following way.

A mixture of vinyl ester resin (SSP50-006 made by Showa Denko K.K.) 100 part by weight, and Parkadox P16 (made by Kayaku Akzo Co.) 0.5 part by weight and Parcure HO (made by NOF Corporation Co.) 0.5 part by weight was stirred by a stirrer for about 20 minutes. The mixture after stirring was left under vacuum condition for about 30 minutes for deaeration. As a result, an uncured resin composition was obtained.

The glass cloth was impregnated into the obtained resin composition, then the glass cloth was put into a hot wave dryer at 80° C. for 30 minutes. In this way, impregnated glass cloth was cured and the light extraction sheet C was produced.

### Comparative Example 1

The organic EL panel D was produced in the same way as example 1 except for the fact that the light extraction sheet D (not including glass cloth), which was produced in the following method, was used instead of the light extraction sheet A.

The light extraction sheet D was produced in the following way.

An acryl polyol (Acrydic 49-394IM <solid content concentration 60%> made by Mitsui Chemicals Co.) 32 part by weight, silica resin particle (mean diameter 27.2 μm) 180 part by weight, silicon resin particle (mean diameter 30 μm) 40 part by weight and butyl acetate 215 part by weight are the composition of the solution for the light extraction sheet. This solution was coated on a 100 μm thick PET film. Then, by drying the PET film, the light extraction sheet D was produced.

### Comparative Example 2

The organic EL panel E was produced in the same way as example 1 except for the fact that the light extraction sheet A was not pasted.

### Comparative Example 3

The organic EL panel F was produced in the same way as example 1 except for the fact that the light extraction sheet A was not pasted and that glass cloth instead of PET film was used as an element substrate constituting the organic EL element main body section.

As element substrate, glass cloth (H201 made by Yunichika glass fiber Co.) dried and cured after being impregnated into a resin varnish, was used as a glass cloth. The resin varnish was prepared and its composition was as follows. Special nobolac type epoxy resin (epicoat 157 made by Mitsubishi Chemical Corporation.) 100 part by weight, 4-methylcyclohexane 1,2-dicarboxilic anhydride 80 part by weight, benzyl dimethyl amine 5 part by weight and dimethylformamide 40 part by weight are stirred and mixed to produce resin varnish.

Evaluation Test

Characteristic evaluation tests were performed about the prepared light extraction sheets A to D and the organic EL panels A to F. Concretely, light extraction sheets A to D were evaluated for haze value and total transparency. On the other hand, the organic EL panels A to F were evaluated for brightness character, weather resistance and noninflammability.

<Evaluation of Haze Value and Total Light Transmittance>

The haze value and the total light transmittance were measured about the produced light extraction sheets A to D with the method described above. [1. Structure of organic EL element]

<Brightness Characteristic Evaluation>

A brightness characteristic was evaluated as follows. First, DC of 2.5 mA/cm² was applied between the anode and cathode of the organic EL panel A to F right after producing them and then the brightness (initial brightness) was measured. The brightness was measured by spectral radiance meter (CS-2000 made by Conica Minolta Inc.).

The brightness of the organic EL panels A to D of the examples 1 to 3 and comparative example 1, which had the light extraction sheets A to D, was compared with the brightness of the organic EL panel E of the comparative example 2 without any light extraction sheet to evaluate the light extraction efficiency. That is, the values representing the brightness of the organic EL panels A to D were divided by the values representing the brightness of the organic EL panel E to obtain the light extraction efficiency. A larger light extraction efficiency shows a better result.

<Weather Resistance Evaluation>

Each organic EL panel A to F was put into a cycle thermo, and heated at 60° C. for 500 hours, then naturally cooled. Thereafter they were left at −20° C. for 500 hours. After the heating and cooling treatment, the brightness of the organic EL panels A to F were measured to evaluate the maintenance rate of brightness, which represents the brightness against the brightness just after production (initial brightness). That is ((maintenance rate of brightness)=(brightness after heating and cooling treatment)/(initial brightness)). The measurement of brightness was made in the same way as the measurement described in <Brightness Characteristic Evaluation>. Yellow discoloration of the organic EL panel A to F after the heating and cooling treatment was observed visually.

<Evaluation of Noninflammability>

Radiant heat 3.5 W/cm² was given to each organic EL panel of the organic EL panels. At the same time, the each organic EL panel of the organic EL panels was exposed to the flame for 5 minutes. The maximum heat release Peek RHR (Rated Heat Release), and total heat release for 2 minutes THR (Total Heat Release) were measured at that time. Further, evaluation about emitting smoke was made at that time. As for the maximum heat release and total heat release, a smaller value shows a better results.

Result of Evaluation

Table 1 shows the result of evaluation.

TABLE 1

| | | | | | Comparative | Comparative | Comparative |
|---|---|---|---|---|---|---|---|
| | | Example 1 | Example 2 | Example 3 | Example 1 | Example 2 | Example 3 |
| Organic EL Panel | No. | A | B | C | D | E | F |
| | Element substrate | PET | PET | PET | PET | PET | Glass cloth |
| Light Extraction | No. | A | B | C | D | — | — |
| Sheet | Substrate | Glass cloth | Glass cloth | Glass cloth | PET | — | — |
| | Light diffusion | Inorganic | vinyl chloride | vinyl ester | acryl resin | — | — |
| | sheet | resin | resin | resin | | | |
| | Haze value (%) | 97 | 95 | 93 | 90 | — | — |
| | Total light | 44 | 40 | 41 | 80 | — | — |
| | transmittance (%) | | | | | | |
| Brightness | Brightness (initial) | 996 | 940 | 958 | 990 | 600 | 320 |
| Characteristic | Light extraction | 166 | 157 | 160 | 165 | 100 | 53 |
| Evaluation | efficiency (%) | | | | | | |
| Weather | Brightness after | 960 | 915 | 920 | 910 | 520 | 270 |
| Resistance | heating and | | | | | | |
| Evaluation | cooling treatment | | | | | | |
| | Maintenance rate | 96 | 97 | 96 | 92 | 87 | 84 |
| | of brightness | | | | | | |
| | Yellow | no | no | no | yes | yes | no |
| | discoloration | | | | | | |
| Evaluation of | Peak RHR | 71 | 142 | 162 | 277 | 250 | 65 |
| Non-flammability | THR (kW * min/m²) | 60 | 100 | 101 | 188 | 90 | 51 |
| | Smoke emission | no | yes, a little | no | yes | yes | no |

As shown in the table 1, the light extraction efficiencies of the organic EL panels A to C (examples 1 to 3) equipped with the light extraction sheet were all good. On the other hand, the light extraction efficiencies of the organic EL panels E and F (comparative examples 2 and 3) not equipped with the light extraction sheet were not good. In these ways, it was proved that the light extraction efficiency becomes good by having the light extraction sheet.

Brightness of the organic EL panel F (comparative example 3) using glass cloth as an element substrate was particularly not good compared with the brightness of the organic EL panels A to E. It is presumed that this result was achieved because the surface smoothness of the glass cloth was not good, compared with PET film. Therefore, inclusion of a glass cloth in the organic EL element is insufficient. The effect of this invention is achieved when a glass cloth is included in the light extraction sheet.

The maintenance rate of brightness of organic EL panels A to C of examples 1 to 3 after heating and cooling treatment were good, compared with the maintenance rate of brightness of organic EL panel D of comparative example 1 and organic panels E and F of the comparative examples 2 and 3. Concretely, the organic EL panels A to C showed high maintenance rate of brightness: 96% to 97%. That is, it was proved that heating and cooling treatment did not generally influence the brightness. However the organic EL panel D had relatively low maintenance rate of brightness. Further, the organic EL panel E and F had the maintenance rate of brightness of 90% or less, which were not good. In addition, the organic EL panels A to C did not turn yellow after the heating and cooling treatment. However, the organic EL panels D and E had yellow discoloration. In this way, if the panel is equipped with the light extraction sheet with glass cloth, yellow discoloration did not appear after the heating and cooling treatment. At the same time, high maintenance rate of brightness was maintained.

Further, because of having the light extracting member including glass cloth, Peak RHR (maximum heat release) and THR (total heat release for 2 minutes) of the organic EL panels A to C showed good results. Notably, although the organic EL panel B of the example 2 emitted a small amount of smoke, its smoke amount was smaller than the organic EL panels of comparative example 1 and 2. In this way, it was proved that if the organic EL panel included glass cloth, the organic EL panel had good noninflammability.

In this way, it was proved that the present invention can provide the organic EL element with both good light extraction efficiency and good weather resistance. Concretely, the organic EL element, which shows good initial brightness, good light extracting efficiency and good weather resistance represented by a good maintenance rate of brightness and prevention of yellow discoloration, can be provided. Further, the organic EL panel of the present invention was proved to have good noninflammability, too.

Therefore, the organic EL element of the present invention could be used for various applications, for example, display or lighting system and the like. In those cases, new functions could be added in each application.

### EXPLANATION OF CODE NUMBERS

1 organic EL element main body section
2 light extraction sheet (Sheet)
3 sealing layer
4 adhesion layer
10 organic EL element

What is claimed is:

1. An organic electroluminescent element comprising:
an organic electroluminescent element main body section having electrodes consisting of an anode and cathode and an organic compound layer disposed between said anode and cathode, said organic compound layer emitting a light when a voltage is applied between said anode and said cathode; and
a light extracting member including a glass cloth provided outside at least one of said anode and cathode, through either or both of which a light emitted from said organic compound layer passes.

2. The organic electroluminescent element according to claim 1,
wherein said light extracting member is bonded to at least one of said anode and said cathode with an adhesive agent layer.
